(19) United States
(12) Patent Application Publication
(10) Pub. No.: US 2009/0291327 A1
(43) Pub. Date: Nov. 26, 2009

(54) MAGNETIC LAMINATED FILM, METHOD OF MANUFACTURING THE SAME, AND MAGNETIC HEAD

(75) Inventor: Junichi Kane, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/357,922

(22) Filed: Jan. 22, 2009

(30) Foreign Application Priority Data
May 26, 2008 (JP) 2008-136498

(51) Int. Cl. G11B 5/33; C23C 14/34; B32B 3/10

(52) U.S. Cl. 428/812; 204/192.15; 428/600; 428/611

(57) ABSTRACT

The magnetic laminated film includes magnetic films having smooth surfaces. The method of manufacturing the magnetic laminated film comprises the steps of: forming a magnetic film including Fe and Co; smoothening a surface of the magnetic film; forming a discontinuous film, which is composed of a magnetic material or an insulating material and which has a thickness to form a discontinuous film, on the smooth surface of the magnetic film; and repeating the above described steps to laminate a plurality of the magnetic films.

### BACKGROUND

The present invention relates to a magnetic laminated film, whose surface has superior smoothness, a method of manufacturing the magnetic laminated film, and a magnetic head using the magnetic laminated film.

In a magnetic disk unit, recording media having high coercive forces (Hc) are used because of increasing plane recording density thereof. However, in case of using the recording media having high coercive forces, a magnetic head must generate a strong write magnetic field, so a write magnetic pole composed of a magnetic material having a high saturation magnetic flux density (high Bs value) has been studied. Further, the write magnetic pole must have superior magnetic response (high-frequency property) and superior soft magnetic characteristics.

In case that the write magnetic pole is composed of the magnetic material having a high Bs value, a high Bs layer is formed adjacent to a write gap, to which magnetic flux concentrate, of a horizontal magnetic head. On the other hand, in a vertical magnetic head, a high Bs layer is formed above a main magnetic pole.

FeCo is known as a high Bs magnetic material and suitably used for forming a write magnetic pole. However, the FeCo has a high Bs value, but a magnetostriction constant is great and soft magnetic characteristics are inferior. To solve the problems, a magnetic laminated film, in which FeCo layers and insulating films are alternately laminated or FeCo layers and NiFe layers having superior soft magnetic characteristics are alternately laminated, was proposed. For example, the magnetic laminated film is disclosed in International Laid-open Publication WO2004/097806 and Japanese Laid-open Patent Publication No. 2007-220850.

In case of forming a FeCo film by sputtering, if the FeCo film is continuously formed, roughness of a surface of the FeCo film will be great. The great roughness will badly influence when fine patterns are formed on the film.

A crystal structure of the FeCo film, which is formed by the continuous film forming process, is shown in FIG. 7. Crystal grains of the FeCo film are large. Thus, if the film is continuously formed until its thickness reaches about 700 nm, crystal grains greatly grow. Therefore, a surface of the FeCo film must be roughened.

In a step of forming a write magnetic pole of a horizontal magnetic head, a high Bs film is formed on a surface of a lower magnetic pole, and then a write gap layer is formed. Further, an upper magnetic pole is formed. In this step, a resist pattern is formed on the high Bs film. Therefore, if roughness of the surface of the high Bs film (FeCo film) is great, the resist pattern cannot be precisely patterned. With increasing plane recording densities of recording media, the write magnetic head must have a fine pattern. Therefore, the resist pattern must be highly precisely formed.

### SUMMARY

An object of the present invention is to provide a magnetic laminated film, in which surface roughness of magnetic films can be reduced and which is capable of precisely forming an upper magnetic pole, etc.

To achieve the objects, the present invention has following structures.

Namely, the method of manufacturing a magnetic laminated film, comprising the steps of: forming a magnetic film including Fe and Co; smoothening a surface of the magnetic film; and repeating said steps to laminate a plurality of the magnetic films.

Further method of manufacturing a magnetic laminated film comprising the step of:

forming a discontinuous film, which is composed of a magnetic material or an insulating material and which has a thickness to form the discontinuous film, on the smooth surface of the magnetic film, after the step of smoothening a surface of the magnetic film;

Another method of manufacturing a magnetic laminated film, comprising the steps of: forming a magnetic film including Fe and Co; forming a discontinuous film, which is composed of a magnetic material or an insulating material and which has a thickness to form the discontinuous film, on the surface of the magnetic film; smoothening a surface of the magnetic film including parts of the discontinuous film; and repeating said steps to laminate a plurality of the magnetic films.

Preferably, a Bs value of the magnetic material constituting the discontinuous film is smaller than that of the magnetic material including Fe and Co. Especially, the magnetic material constituting the discontinuous film is NiFe.

Preferably, ion milling or reverse sputtering is performed in the above described smoothing step.

The magnetic laminated film of the present invention comprises: a plurality of magnetic films including Fe and Co; and a plurality of discontinuous films being composed of a magnetic material or an insulating material, the magnetic films and the discontinuous films are alternately laminated, and a surface of each of the magnetic films is smooth.

The magnetic head includes a write head, which has a magnetic layer, the magnetic layer is constituted by a magnetic laminated film comprising: a plurality of magnetic films including Fe and Co; and a plurality of discontinuous films being composed of a magnetic material or an insulating material, the magnetic films and the discontinuous films are alternately laminated, and a surface of each of the magnetic films is smooth.

In case that the magnetic laminated film is used as a magnetic layer adjacent to a write gap, a strong magnetic field can be generated in the vicinity of the write gap, and the write magnetic pole having a fine pattern can be formed.

In the method of the present invention, the magnetic laminated film having the smooth surface can be manufactured, and the write magnetic pole having a fine pattern can be formed. The magnetic laminated film of the present invention can have a high Bs value and has superior soft magnetic characteristics. For example, the magnetic laminated film can be suitably used as a magnetic layer of the write magnetic pole of the magnetic head.

### BRIEF DESCRIPTION OF THE DRAWINGS

Embodiments of the present invention will now be described by way of examples and with reference to the accompanying drawings, in which:

FIGS. 1A-1D are explanation views showing a manufacturing process of a magnetic laminated film of the present invention;

FIGS. 2A-2C are explanation views showing further steps of the manufacturing process;

FIG. 3 is a flow chart showing the manufacturing process;

FIGS. 4A-4C are flow charts showing other manufacturing processes;

FIGS. 5A and 5B are sectional views of magnetic heads using the magnetic laminated film;

FIG. 6 is a sectional view of the magnetic laminated film used in a write magnetic pole; and

FIG. 7 is an explanation view of a FeCo film, which is formed by a continuous film forming process.

### DETAILED DESCRIPTION OF THE EMBODIMENTS

Preferred embodiments of the present invention will now be described in detail with reference to the accompanying drawings.

### (Method of Manufacturing Magnetic Laminated Film)

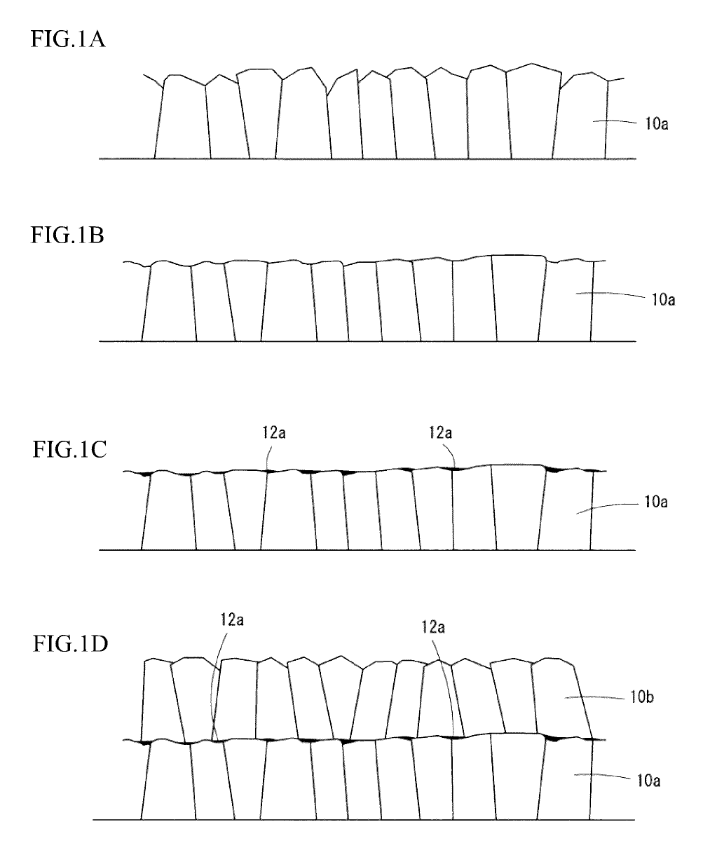

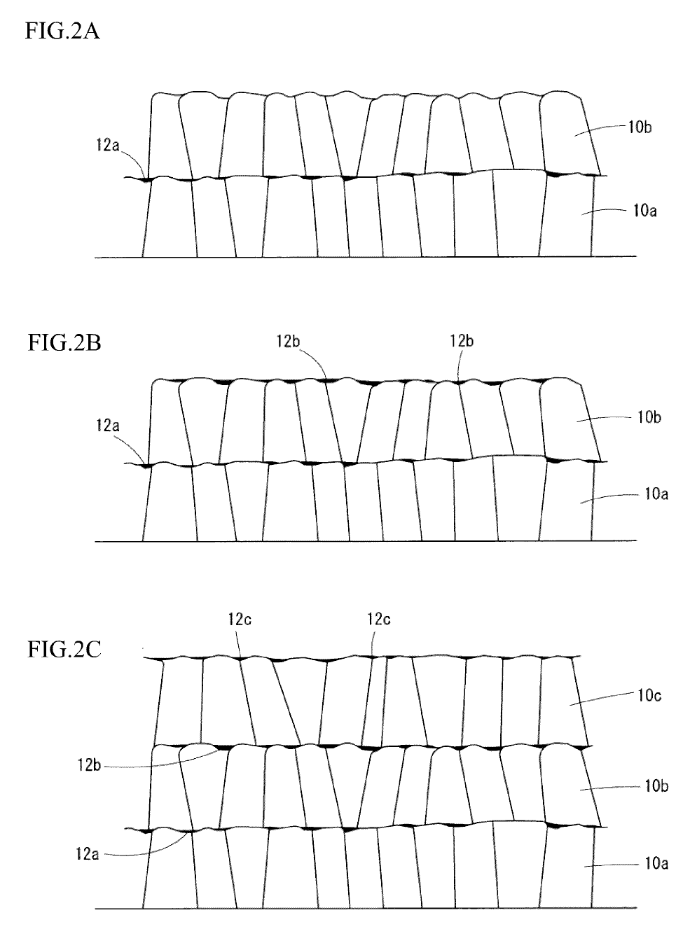

FIGS. 1A-2C show film structures respectively formed in the steps of manufacturing the magnetic laminated film of the present invention.

In the method of the present invention, each of magnetic films is constituted by a plurality of layers, and the layers are separately formed. The present embodiment is characterized in that each of FeCo films is constituted by a plurality of layers which are separately formed, that a surface of the FeCo film is smoothened, by ion milling or reverse sputtering, after forming the FeCo film, and that a discontinuous NiFe film is formed on the smoothened surface of the FeCo film. The FeCo film is composed of a high Bs material, and the NiFe film is composed of a soft magnetic material whose Bs value is smaller than that of the FeCo film.

In FIG. 1A, a first FeCo film 10a is formed on a surface of a substrate by sputtering. In case of forming the FeCo film 10a by sputtering, crystal grains of FeCo grow and a surface of the FeCo film 10a is roughened. In the present embodiment, a thickness of the first FeCo film 10a is 230 nm.

The first FeCo film 10a is formed by an ordinary sputtering technique using FeCo as a target. Sputtering conditions will be explained. For example, a magnetron RF sputtering apparatus is used, a RF power is 3000 W, and the sputtering is performed in an Ar gas atmosphere.

Next, the surface of the first FeCo film 10a is smoothened by ion milling or reverse sputtering. FIG. 1B explanatorily shows the surface of the first FeCo film 10a which has been smoothened by ion milling or reverse sputtering.

By performing ion milling or reverse sputtering, the surface of the first FeCo film 10a is smoothened and FeCo particles sputtered from the surface fill microfine concaves formed in the surface of the first FeCo film 10a. Therefore, the surface of the first FeCo film 10a can be highly smoothened.

Conditions of the ion milling will be explained. For example, Ar ions are accelerated by a grid mounted type ion milling apparatus, and the ion milling is performed by the Ar ions. In comparison with the reverse sputtering, the ion milling is capable of suitably evenly milling an entire wafer. Further, controllability of an amount of ion milling is superior to that of reverse sputtering.

On the other hand, the reverse sputtering may be performed in the sputtering apparatus, in which the first FeCo film 10a has been formed, by applying inverse voltage between the target and the substrate. For example, the reverse sputtering is performed, in the Ar atmosphere, for about 1-2 minutes with applying RF 500 W. An advantage of employing the reverse sputtering is that the film forming process and the smoothening treatment can be performed in the same apparatus.

Next, a NiFe film 12a is formed on the surface of the first FeCo film 10a as shown in FIG. 5C. The NiFe film 12a is formed by sputtering, and the sputtering is performed until a thickness of the NiFe film 12a reaches about 20 nm. Namely, the NiFe film 12a is such the thin film, so that the NiFe film 12a is separately formed in the microfine concaves existing in the surface of the first FeCo film 10a or the NiFe film 12a is discontinuously formed on the surface of the first FeCo film 10a in the step of forming the NiFe film 12a on the surface of the first FeCo film 10a.

It is known that soft magnetic characteristics of the magnetic laminated film can be improved, without reducing the Bs value, by forming the discontinuous NiFe film 12a on the surface of the first FeCo film 10a (see Japanese Laid-open Patent Publication No. 2007-220850).

Further, by forming such the thin NiFe film 12a capable of sticking in and filling the microfine concaves in the surface of the first FeCo film 10a, the surface of the first FeCo film 10a can be flattened and further smoothened.

In FIG. 1D, a second FeCo film 10b is formed. The second FeCo film 10b is formed, by sputtering, until reaching a thickness of 230 nm as well as the first FeCo film 10a.

Since the surface of the first FeCo film 10a is highly smoothened by not only the smoothening treatment, e.g., revere sputtering, but also forming the NiFe film 12a, microfine projections and microfine concaves of the surface are not enhanced by laminating the second FeCo film 10b.

In FIG. 2A, a surface of the second FeCo film 10b is smoothened by, for example, reverse sputtering. By the smoothening treatment, the surface of the second FeCo film 10b is smoothened.

In FIG. 2B, a second NiFe film 12b is formed on the surface of the second FeCo film 10b. The NiFe film 12b is also formed into the thin film having a thickness of 20 nm. The second NiFe film 12b is a discontinuous film as well as the first NiFe film 12a.

In FIG. 2C, a third FeCo film 10c is formed after forming the second NiFe film 12c. A surface of the third FeCo film 10c is smoothened, and then a third NiFe film 12c is formed thereon.

A thickness of the third FeCo film 10c is 230 nm. Therefore, a total thickness of the FeCo films is about 700 nm.

A surface of the third FeCo film 10c is also smoothened as well as the first and second FeCo films 10a and 10b. The third NiFe film 12c has a thickness of 20 nm, as well as the first and second NiFe films 12a and 12b, so as to stick in and fill microfine concaves existing in the surface of the third FeCo film 10c.

The surface of the third FeCo film 10c is smoothened by the smoothening treatment, and then the third NiFe film 12c is formed. Therefore, the microfine projections and microfine concaves in the surface of the third FeCo film 10c can be highly smoothened.

A plurality of the FeCo films are separately formed, the surfaces of the FeCo films are smoothened by sputtering, and the discontinuous NiFe films are respectively formed on the smoothened surfaces of the FeCo films. Therefore, a rough surface of the magnetic laminated film, which is mainly composed of FeCo, can be made highly smoothened.

Measured surface roughness of samples are shown in TABLE 1, wherein Comparative Example 1 was a FeCo film, which was continuously formed until reaching a thickness of 700 nm; Comparative Example 2 was a three-layered FeCo film, in which three FeCo films were laminated and discontinuous NiFe films were respectively formed between the adjacent FeCo films, having a total thickness of 700 nm; and Examples were the magnetic laminated films manufactured by the above described method.

TABLE 1

| | Rₐ (nm) | Rₘₐₓ (nm) |
|---|---|---|
| Comparative Example 1 | 8 | 112 |
| Comparative Example 2 | 5.3 | 72 |
| Examples | 2-3 | 30-50 |

According to the results shown in TABLE 1, in case of continuously forming the FeCo film until reaching the thickness of 700 nm (Comparative Example 1), a value of Rₘₐₓ (maximum level difference between the microfine projection and the microfine concave) was more than 100 nm; in the Examples, the values of Rₘₐₓ were less than half thereof.

In comparison with Comparative Example 2, in which the FeCo films were separately formed and the discontinuous NiFe films formed therebetween, the values of Rₘₐₓ were reduced about 20 nm or more.

Therefore, the method of manufacturing the magnetic laminated film relating to the present invention was capable of effectively improving the smoothness of the surface of the magnetic laminated films.

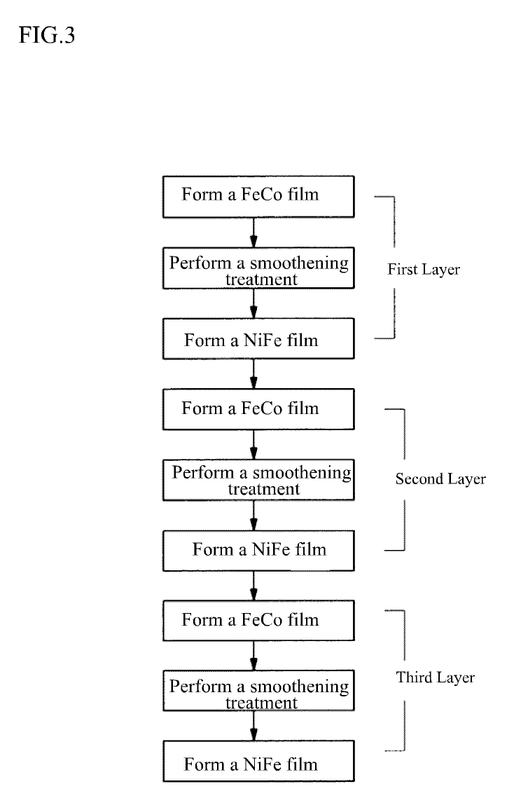

A flowchart of the manufacturing method of the above described embodiment is shown in FIG. 3. According to the flowchart, the step of forming the FeCo film, the step of smoothening the surface of the FeCo film and the step of forming the discontinuous NiFe film are repeated so as to form the magnetic laminated film.

In the present embodiment, both of FeCo and NiFe are magnetic materials, so the magnetic laminated film can be manufactured in the same sputtering apparatus, in which targets of FeCo and NiFe are provided.

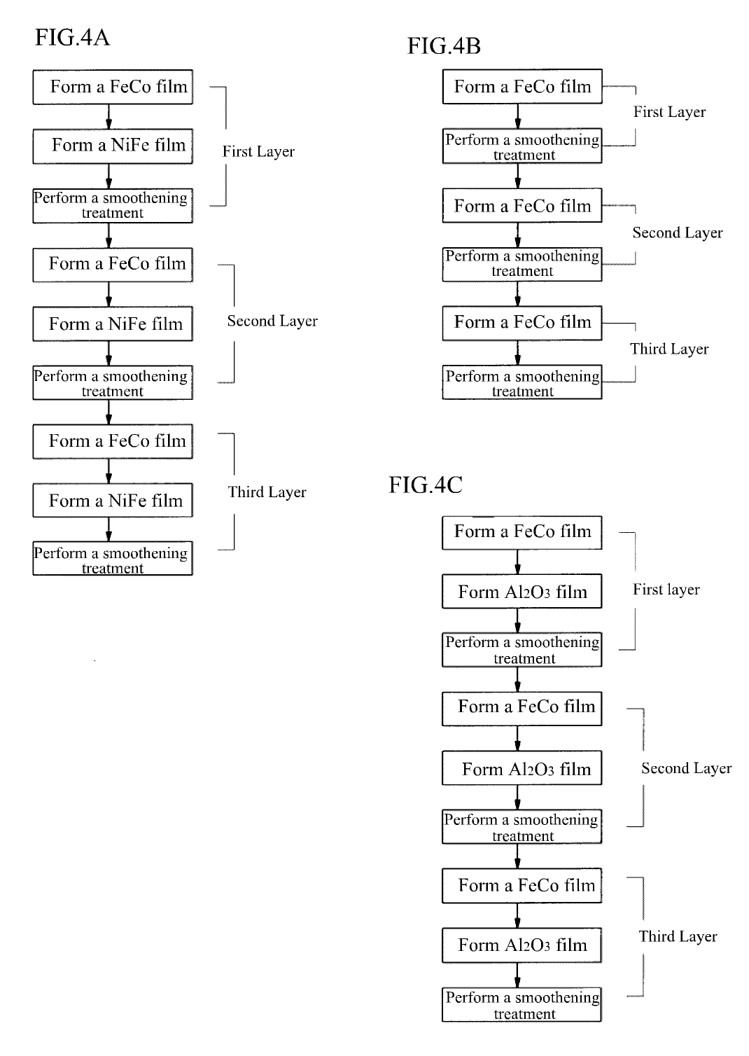

Other methods relating to the present invention are shown in FIGS. 4A-4C.

In FIG. 4A, firstly a FeCo film is formed, secondly a NiFe film, whose Bs value is less than that of the FeCo film, is formed without performing the smoothening treatment, and then the smoothening treatment is performed. These steps are repeated to form the magnetic laminated film. In this method too, thicknesses of the NiFe films are controlled so as to form the discontinuous NiFe films on the surfaces of the FeCo films. By performing the smoothening treatment after forming each of the NiFe films, the surface roughness of the magnetic laminated film can be improved.

In case of performing ion milling as the smoothening treatment, a vacuum state of an ion milling apparatus is broken and another apparatus must be used. In this case, the laminated film contacts the air, so the surface of the laminated film will be oxidized. However, in the present method shown in FIG. 4A, the NiFe film is formed on the surface of the laminated film, so that oxidizing the important FeCo film can be prevented.

In FIG. 4B, the step of forming the FeCo film and the step of smoothening the surface of the FeCo film are repeated to form the magnetic laminated film. In this method, the step of forming the NiFe film is omitted. After forming the FeCo film, the surface is smoothened by reverse sputtering, so that the surface roughness of the magnetic laminated film can be reduced.

Note that, in the above described embodiment, the discontinuous NiFe film is formed between the FeCo films, so that the Bs value of the entire magnetic laminated film can be increased. Further, in comparison with the case of using the FeCo films only, soft magnetic characteristics can be improved. In the method shown in FIG. 4B, the effect of improving the soft magnetic characteristics is limited, but the surface roughness can be effectively improved. Further, forming the FeCo films and the reverse sputtering for the smoothing treatment can be serially performed in a film forming step.

In FIG. 4C, films composed of Al₂O₃ are used instead of the NiFe films, each of which is formed between the FeCo films. It is known that a magnetic laminated film, in which FeCo films are laminated and insulating films are formed between the FeCo films, has high Bs value and superior soft magnetic characteristics (see International Laid-open Publication WO2004/097806). In the method shown in FIG. 4C too, insulating films are formed between the FeCo films. The smoothening treatment is performed after forming the insulating film, and then the insulating film composed of Al₂O₃ is formed as the discontinuous film. With this structure, the surface roughness of the magnetic laminated film can be reduced as well as the case of using the discontinuous NiFe films.

In this method too, the discontinuous Al₂O₃ films fill microfine concaves existing on surfaces of the FeCo films, so that the surfaces of the FeCo films can be flattened.

Further, the method shown in FIG. 4C may be modified. Namely, the magnetic laminated film may be manufactured by forming the FeCo film, forming the Al₂O₃ discontinuous film, performing the smoothening treatment and repeating the steps a prescribed times.

In the above described embodiments, the FeCo film is used as the magnetic material having a high Bs value. An alloy including Fe and/or Co may be used as the high Bs material of the magnetic laminated film. The alloy has high saturation magnetic flux density. The alloy may include at least one of O, N and C. And, the alloy may further include at least one of Al, B, Ga, Si, Ge, Y, Ti, Zr, Hf, V, Nb, Ta, Cr. Ni, Mo, Rh, Pd and Pt.

The above described magnetic laminated films have the three-layered structures, but number of layers is not limited. For example, the magnetic laminated film may have a two-layered structure and a four or more-layered structure. The thicknesses of the magnetic films and the total thickness of the magnetic laminated film may be optionally selected.

### (Magnetic Head)

Magnetic heads, in each of which the magnetic laminated film described above is used in a write magnetic pole, are shown in FIGS. 5A and 5B.

FIG. 5A shows a horizontal magnetic head; FIG. 5B shows a vertical magnetic head.

In FIG. 5A, the magnetic head includes: a read head 8 having a read element 5, a lower shielding layer 6 and an upper shielding layer 7; and a write head 20 having a lower magnetic pole 16, an upper magnetic pole 17 and a write gap 15 formed therebetween. Coils 19, which are wound around a back gap section 18, are located on the rear side of the lower magnetic pole 16.

The above described magnetic laminated film is provided to an end part 16a of the lower magnetic pole 16.

In FIG. 5B, the magnetic head includes: a read head 30 having a read element 31, a lower shielding layer 32 and an upper shielding layer 33; and a write head 40 having a main magnetic pole 41, a return yoke 42 and write coils 44. A trailing shield 43 is located at a front end of the return yoke 42 to face the main magnetic pole 41.

The above described magnetic laminated film is provided to the main magnetic pole 41.

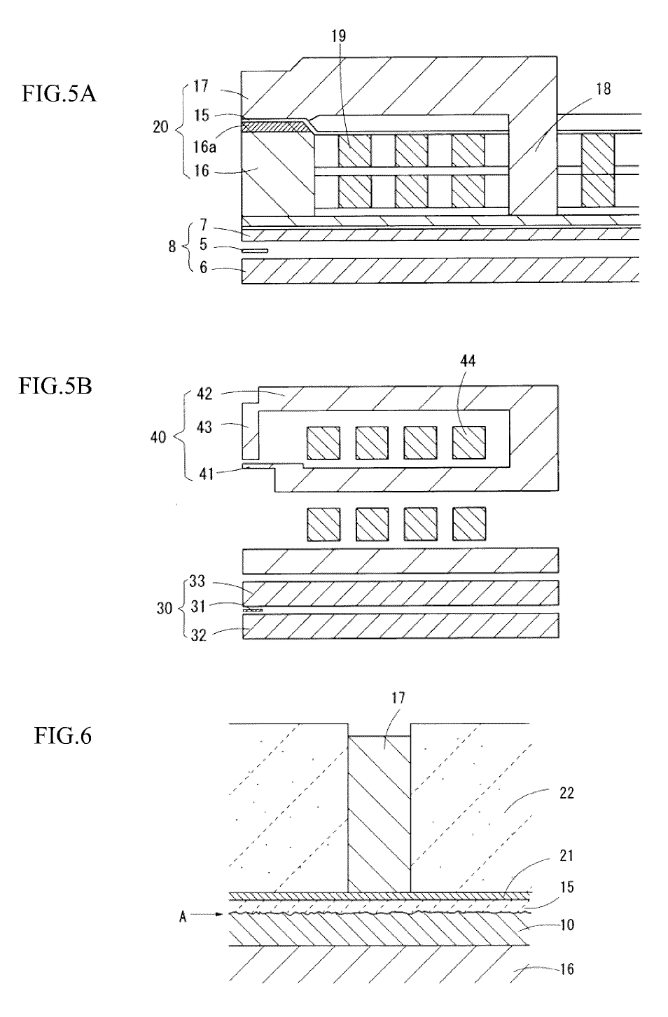

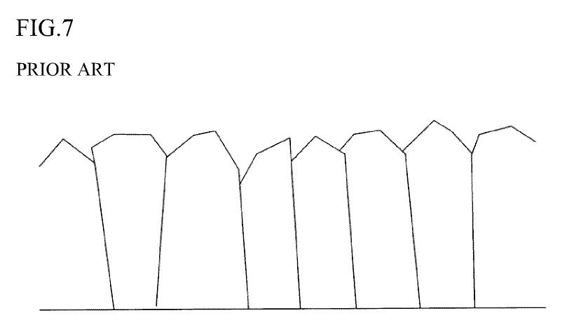

In FIG. 6, the magnetic laminated film 10, which is provided to the end part 16a of the lower magnetic pole 16 of the horizontal magnetic head, is enlarged. FIG. 6 is a sectional view, along an air bearing surface, wherein the magnetic laminated film 10 is formed on the lower magnetic pole 16, the write gap 15 is formed, a plating seed layer 21 is formed, and then the upper magnetic pole 17 is formed by plating. To form the upper magnetic pole 17 into a prescribed pattern, a resist pattern 22 is formed on a surface of the plating seed layer 21, and the upper magnetic pole 17 is formed by electrolytic plating, in which the plating seed layer 21 is used as an electric power feeding layer.

Since the resist pattern 22 is patterned by optically exposing and developing, a patterning accuracy is influenced by a condition of a surface of a base layer, which is indicated by an arrow A. By using the magnetic laminated film of the present invention as the laminated film 10, the surface roughness of the magnetic laminated film can be reduced and the patterning accuracy of the resist pattern 22 can be improved. Therefore, the write magnetic pole having fine patterns can be highly precisely formed.

In the horizontal magnetic head shown in FIG. 5A, the magnetic layer having a high Bs value and superior soft magnetic characteristics is formed in the end part 16a of the lower magnetic pole 16. With this structure, a strong magnetic field can be generated in the vicinity of the write gap, so that the magnetic head is capable of recording data with high recording density.

In the vertical magnetic head shown in FIG. 5B too, the magnetic layer having a high Bs value and superior soft magnetic characteristics is formed in the main magnetic pole 41. With this structure, the magnetic head, which has high resolution and which is capable of recording data with high recording density, can be manufactured.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A method of manufacturing a magnetic laminated film,
comprising the steps of:
forming a magnetic film including Fe and Co;
smoothening a surface of the magnetic film; and
repeating said steps to laminate a plurality of the magnetic films.

2. The method according to claim 1,
further comprising the step of:
forming a discontinuous film, which is composed of a magnetic material or an insulating material and which has a thickness to form the discontinuous film, on the smooth surface of the magnetic film, after the step of smoothening a surface of the magnetic film;

3. A method of manufacturing a magnetic laminated film,
comprising the steps of:
forming a magnetic film including Fe and Co;
forming a discontinuous film, which is composed of a magnetic material or an insulating material and which has a thickness to form the discontinuous film, on the surface of the magnetic film;
smoothening a surface of the magnetic film including parts of the discontinuous film; and
repeating said steps to laminate a plurality of the magnetic films.

4. The method according to claim 2,
wherein a Bs value of the magnetic material constituting the discontinuous film is smaller than that of the magnetic material including Fe and Co.

5. The method according to claim 3,
wherein a Bs value of the magnetic material constituting the discontinuous film is smaller than that of the magnetic material including Fe and Co.

6. The method according to claim 4,
wherein the magnetic material constituting the discontinuous film is NiFe.

7. The method according to claim 5 wherein the magnetic material constituting the discontinuous film is NiFe.

8. The method according to claim 1,
wherein ion milling or reverse sputtering is performed in said smoothing step.

9. The method according to claim 2,
wherein ion milling or reverse sputtering is performed in said smoothing step.

10. The method according to claim 3
wherein ion milling or reverse sputtering is performed in said smoothing step.

11. A magnetic laminated film,
comprising:
a plurality of magnetic films including Fe and Co; and
a plurality of discontinuous films being composed of a magnetic material or an insulating material,
wherein the magnetic films and the discontinuous films are alternately laminated, and
a surface of each of the magnetic films is smooth.

12. A magnetic head including a write head, which has a magnetic layer,
wherein the magnetic layer is constituted by a magnetic laminated film comprising: a plurality of magnetic films including Fe and Co; and a plurality of discontinuous films being composed of a magnetic material or an insulating material,
the magnetic films and the discontinuous films are alternately laminated, and
a surface of each of the magnetic films is smooth.

13. The magnetic head according to claim 12,
wherein the magnetic laminated film is used as a magnetic layer adjacent to a write gap.
